(19) United States
(12) Patent Application Publication
(10) Pub. No.: US 2016/0240737 A1
(43) Pub. Date: Aug. 18, 2016

(54) LIGHT-EMITTING DEVICE AND PRODUCTION METHOD THEREFOR

(71) Applicant: TOYODA GOSEI CO., LTD., Kiyosu-shi (JP)

(72) Inventors: Kimiyasu IDE, Kiyosu-shi (JP); Shingo TOTANI, Kiyosu-shi (JP)

(21) Appl. No.: 15/016,137

(22) Filed: Feb. 4, 2016

(30) Foreign Application Priority Data
Feb. 12, 2015 (JP) 2015-025726

(51) Int. Cl. H01L 33/22; H01L 33/58; H01L 33/32

(52) U.S. Cl. CPC H01L 33/22; H01L 33/32; H01L 33/58; H01L 2933/0058; H01L 2933/0033

(57) ABSTRACT

The present invention provides a light-emitting device exhibiting improved light extraction performance. The light-emitting device is of a flip-chip type wherein a Group III nitride semiconductor layer is disposed on one surface of a GaN substrate, light is extracted from a rear surface of the substrate (the other surface of the substrate), and an uneven structure is formed on the rear surface of the substrate. An antireflection film is continuously formed on the uneven structure and the side surfaces of the GaN substrate. The antireflection film is a single layer made of Al₂O₃ having a refractive index smaller than that of the GaN substrate and larger than that of the sealing material. Moreover, the antireflection film is formed along the ridges and recesses of the uneven structure without being filled. The antireflection film prevents reflection between the GaN substrate and the sealing material, thereby improving the light extraction performance.

### BACKGROUND OF THE INVENTION

1. Field of the Invention

The present invention relates to a flip-chip type Group III nitride semiconductor light-emitting device using a Group III nitride semiconductor substrate and exhibiting improved light extraction performance. The present invention also relates to a production method therefor.

2. Background Art

Conventionally, in the flip-chip type Group III nitride semiconductor light-emitting device, a concave and convex structure is formed on a rear surface of a sapphire substrate (a surface opposite to the surface on which a semiconductor layer is formed) to improve light extraction performance. Moreover, when the flip-chip type light-emitting device is resin sealed, the sapphire substrate is covered with a resin material, and there is a reflection at an interface between the resin material and the sapphire substrate, resulting in deterioration of light extraction performance. Therefore, an antireflection film is formed on the rear surface of the sapphire substrate to reduce reflection between the rear surface of the sapphire substrate and the resin material, thereby improving the light extraction performance.

A sapphire substrate has been widely used as a growth substrate of the Group III nitride semiconductor light-emitting device. Recently, a GaN substrate has come to be used.

Patent Document 1: Japanese Patent Application Laid-Open (kokai) No. 2001-217467

Patent Document 2: Japanese Patent Application Laid-Open (kokai) No. 2006-128202

In the flip-chip type Group III nitride semiconductor light-emitting device using the GaN substrate, the GaN substrate comes into contact with the sealing resin when resin sealed. However, more light is reflected at the interface between the resin and the GaN substrate because of a large relative refractive index difference between the resin material and GaN. There was a problem that the light extraction performance is not sufficiently improved simply by forming the concave and convex structure on the rear surface of the GaN substrate or the antireflection film.

### SUMMARY OF THE INVENTION

In view of the foregoing, an object of the present invention is to improve light extraction performance in a flip-chip type Group III nitride semiconductor light-emitting device using a Group III nitride semiconductor substrate.

In one aspect of the present invention, there is provided a flip-chip type light-emitting device in which a Group III nitride semiconductor layer is disposed on one surface of a Group III nitride semiconductor substrate, and other surface of the substrate is covered with a sealing material, the light-emitting device comprising:

an uneven structure with ridges and recesses formed on a surface opposite to the semiconductor layer side of the substrate; and

an antireflection film formed continuously on the uneven structure and side surfaces of the substrate along the ridges and recesses of the uneven structure without being filled in recesses, which is made of a material having a refractive index smaller than that of the substrate and larger than that of the sealing material to prevent reflection between the substrate and the sealing material by the interference of light; and

wherein areas of the side surfaces of the substrate at the uneven structure side are inclined with respect to a vertical direction of the main surface of the substrate, and other areas of the side surfaces of the substrate are vertical to the main surface of the substrate; and

wherein the antireflection film is formed on the inclined side surface areas of the substrate and not formed on the vertical side surface areas of the substrate.

In the present specification, unless otherwise specified, the refractive index is a value at the peak emission wavelength.

The sealing material to seal the light-emitting device includes silicone resin, epoxy resin, and glass.

The antireflection film may be formed of any material having a refractive index smaller than that of the substrate and larger than that of the sealing material. When a GaN substrate is employed, the antireflection film may be formed of, for example, HfO₂, ZrO₂, AlN, SiN, TiO₂, and Ta₂O₅.

The antireflection film may be a single layer or a plurality of layers.

The thickness of the antireflection film is, preferably, 80 nm to 100 nm. Such a thickness can further prevent reflection and improve the transmittance, thereby improving the light extraction performance of the light-emitting device.

The standard deviation of the thickness of the antireflection film is, preferably, not more than 10 nm. Such a uniform thickness can improve the light extraction performance. The antireflection film having such a uniform thickness can be formed, for example, through ALD.

In the other aspect of the present invention, there is provided a method for producing a flip-chip type light-emitting device in which a Group III nitride semiconductor layer is disposed on one surface of a Group III nitride semiconductor substrate, and other light output surface of the substrate is covered with a sealing material, the method for producing the light-emitting device comprising the steps of forming an isolation trench on the light output surface of the substrate to separate a wafer for each device; forming an uneven structure with ridges and recesses on the light output surface of the substrate; and forming an antireflection film continuously along the ridges and recesses of the uneven structure and the side surfaces of the substrate through ALD, which is made of a material having a refractive index smaller than that of the substrate and larger than that of the sealing material to prevent reflection between the substrate and the sealing material by the interference of light.

In the step of forming an isolation trench, the isolation trench may be formed by laser scanning, dry etching, and dicer cutting. Particularly, laser scanning is preferable because a deep isolation trench can be formed without destroying the substrate.

In the step of forming an uneven structure, the uneven structure may be formed, for example, by wet etching.

In the present invention, an antireflection film having a uniform thickness is formed along the ridges and recesses on the rear surface of the substrate and the side surfaces of the substrate, thereby improving the light extraction performance of the light-emitting device.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 shows a structure of a light-emitting device according to Embodiment 1;

FIGS. 2A to 2F are sketches showing processes for producing the light-emitting device according to Embodiment 1;

FIG. 3 is a graph showing the comparison of the light outputs between the light-emitting device according to Embodiment 1 and the light-emitting device according to Comparative Example; and

FIG. 4 is a graph showing the relationship between the angle average of transmittance and the thickness of Al₂O₃ layer.

### DETAILED DESCRIPTION OF PREFERRED EMBODIMENT

A specific embodiment of the present invention will next be described with reference to the drawings. However, the present invention is not limited to the embodiment.

### Embodiment 1

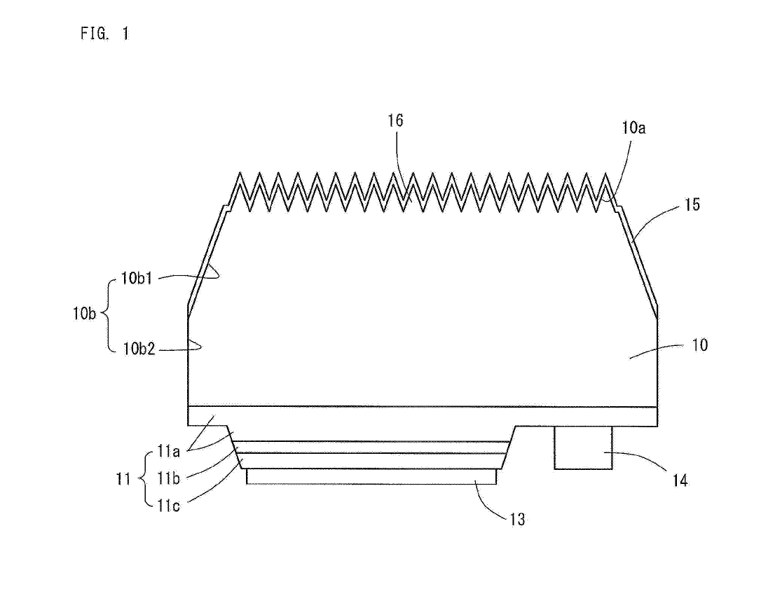

FIG. 1 shows a structure of a flip-chip type light-emitting device according to Embodiment 1. As shown in FIG. 1, the light-emitting device according to Embodiment 1 comprises a GaN substrate 10; a Group III nitride semiconductor layer 11 disposed on a surface of the GaN substrate 10, in which an n-type layer 11a, a light-emitting layer 11b, and a p-type layer 11c are sequentially deposited from the GaN substrate 10 side; a p-electrode 13; an n-electrode 14; and an antireflection film 15. The light-emitting device according to Embodiment 1 has a flip-chip type (face-down type) structure which reflects light emitted from the light-emitting layer 11b by the p-electrode 13, transmits the light through the GaN substrate 10, and extracts the light from a rear surface 10a of the GaN substrate 10.

The GaN substrate 10 has a c-plane main surface. On a surface having Ga polarity (hereinafter, referred to as a surface) of two surfaces of the GaN substrate 10, a semiconductor layer 11 is formed. Moreover, on the rear surface 10a of the GaN substrate 10 (a surface opposite to the semiconductor layer 11 side, a surface having N polarity), an uneven structure 16 is formed.

The uneven structure 16 has a structure in which a plurality of fine projections and grooves (ridges and recesses or convexes and concaves) are randomly and two-dimensionally arranged. Each of the projections or grooves has a cone or pyramid shape. Such uneven structure 16 is obtained by wet etching the rear surface 10a of the GaN substrate 10. The method for forming an uneven structure will be described later. An angle between the main surface of the GaN substrate 10 and side surfaces of ridges and recesses falls within a range of 110° to 130°. The depth of the uneven structure is 0.1 μm to 10 μm. The light confined in the GaN substrate 10 can be extracted from the rear surface 10a of the GaN substrate 10 by the uneven structure 16, thereby improving the light extraction performance.

The uneven structure 16 may be a moth-eye structure in which the projections are periodically arranged and the arrangement period of the projections is equal to or smaller than the emission wavelength.

Of the side surfaces 10b of the GaN substrate 10, areas 10b1 of the rear surface 10a side of the GaN substrate 10 (the uneven structure 16 side) are inclined so that the cross section parallel to the main surface of the GaN substrate 10 is decreased toward the rear surface 10a of the GaN substrate 10. The inclination angle falls within a range of 140° to 160° to the main surface of the GaN substrate 10. Of the side surfaces 10b of the GaN substrate 10, areas 10b2 of the semiconductor layer 11 side of the GaN substrate are vertical to the main surface of the GaN substrate 10 (at an angle of 80° to 90° to the main surface of the GaN substrate, considering errors). A partial area of the side surfaces 10b of the GaN substrate 10 is inclined because an isolation trench 20 was formed on the rear surface 10a of the GaN substrate 10 to easily separate a wafer for each device in the method for producing the light-emitting device according to Embodiment 1. The details will be described in the method for producing the light-emitting device later.

The semiconductor layer 11 is formed of Group III nitride semiconductor, in which an n-type layer 11a, a light-emitting layer 11b, and a p-type layer 11c are sequentially deposited from the GaN substrate 10 side on the surface of the GaN substrate 10. The n-type layer 11a has a structure in which an n-type contact layer, an ESD layer, and an n-type cladding layer are sequentially deposited from the GaN substrate 10 side. The light-emitting layer 11b has a MQW structure in which a well layer and a barrier layer are repeatedly deposited. The p-type layer 11c has a structure in which a p-type cladding layer and a p-type contact layer are sequentially deposited from the light-emitting layer 1b side.

The p-electrode 13 is formed so as to cover almost the entire surface of the p-type layer 11c. The p-electrode 13 is a reflective electrode which reflects the light emitted from the light-emitting layer 11b to the GaN substrate 10. The p-electrode 13 may be formed of, for example, Ag, Al, or alloy mainly containing Ag or Al.

A part of the semiconductor layer 11 is etched, and a trench is formed so as to have a depth reaching the n-type layer 11a from the surface of the p-type layer 11c (the surface opposite to the light-emitting layer 11b side). The n-electrode 14 is formed on the n-type layer 11a exposed at the bottom surface of the trench.

The structures of the semiconductor layer 11, the p-electrode electrode 13, and the n-electrode 14 are not limited to the above. Any structure employed as a flip-chip type structure of the conventional Group III nitride semiconductor light-emitting device may be employed.

The antireflection film 15 is continuously formed along the rear surface 10a and the side surfaces 10b of the GaN substrate 10. However, in the area of the side surfaces 10b, the antireflection film 15 is formed only on the inclined areas 10b1 of the side surfaces 10b of the rear surface 10a side of the GaN substrate 10, and not formed on the remaining areas (vertical areas 10b2 of the side surfaces 10b of the semiconductor layer 11 side of the GaN substrate 10). Moreover, the antireflection film 15 is formed along the ridges and recesses of the uneven structure 16 without being filled on the rear surface 10a side of the GaN substrate 10.

The antireflection film 15 is formed to prevent reflection at the interface between the rear surface 10a of the GaN substrate 10 and the sealing material and at the interface between the side surfaces 10b of the GaN substrate 10 and the sealing material and thereby to improve the light extraction performance. Reflection is prevented by the interference of light. The reflected lights interfere with each other to weaken each other by that the refractive index is set to an intermediate value between the refractive indices of the GaN substrate 10 and the sealing material and the thickness of the antireflection film 15 is set to a specific value, thereby preventing light reflection. Moreover, the antireflection film 15 is formed to cover the uneven structure 16, thereby improving the durability or chemical resistance of the uneven structure 16 formed on the rear surface 10a of the GaN substrate 10.

As the material sealing the light-emitting device according to Embodiment 1, a resin material such as silicone resin and epoxy resin, or glass is employed.

The antireflection film 15 has a very uniform thickness of 100 nm, and the standard deviation is not more than 10 nm. This is because the antireflection film 15 is formed by ALD. More preferably, the standard deviation is not more than 5 nm. The antireflection film 15 formed on the uneven structure 16 and the antireflection film 15 formed on the areas 10b1 on the side surfaces 10b of the GaN substrate 10 have the same thickness.

The thickness of the antireflection film 15 is not limited to the above, and any other thickness may be employed as long as reflection is reduced by the interference of light. Preferably, the thickness of the antireflection film 15 is 80 nm to 100 nm. Within this range, the antireflection film 15 has a high light transmittance in the emission wavelength range of the Group III nitride semiconductor light-emitting device (for example, peak wavelength of 400 nm to 500 nm, especially 440 nm to 460 nm). More preferably, the thickness of the antireflection film 15 is 85 nm to 95 nm.

In Embodiment 1, the antireflection film 15 is made of Al₂O₃ having a refractive index of 1.65, and any material may be used as long as the refractive index is smaller than that of the GaN substrate 10 and larger than that of the sealing material. The refractive index of GaN is 2.4, and when the sealing material is resin, the refractive index of resin is approximately 1.5. Therefore, the refractive index of the antireflection film 15 may be more than 1.5 and less than 2.4, more preferably, 1.6 to 2.3, and further preferably, 1.7 to 2.2. For example, the antireflection film 15 may be formed of HfO₂, ZrO₂, AlN, SiN, TiO₂, and Ta₂O₅ other than Al₂O₃.

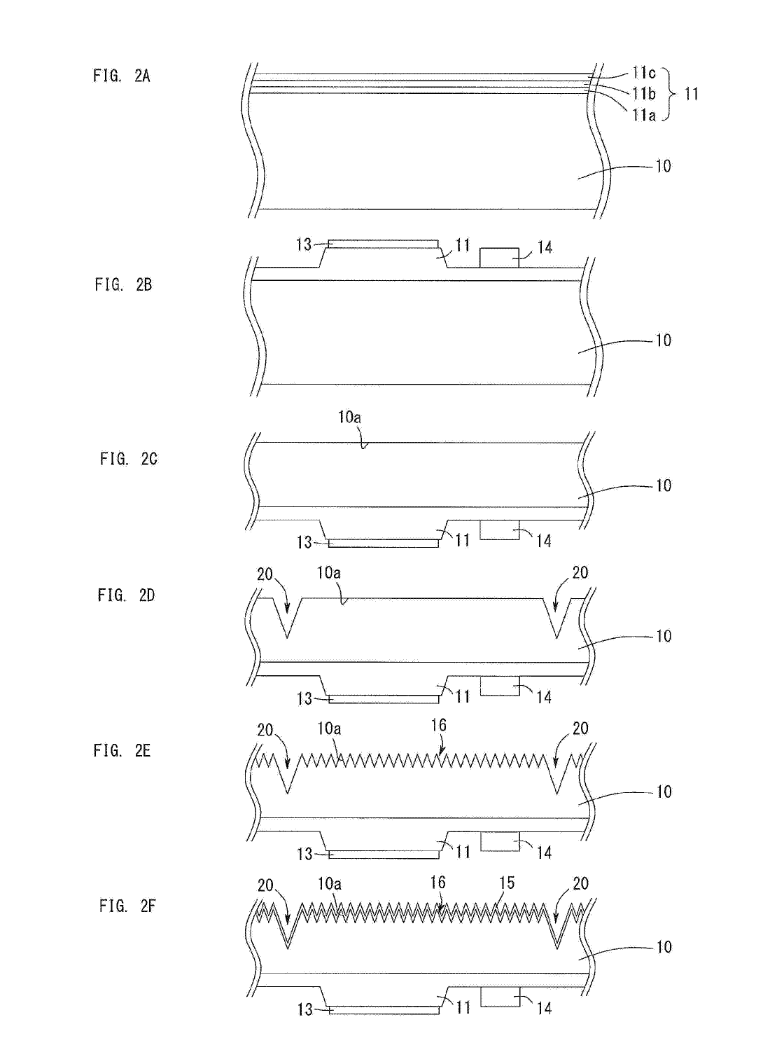

Next will be described the processes for producing the light-emitting device according to Embodiment 1 with reference to FIG. 2.

Firstly, a semiconductor layer 11 is formed by forming an n-type layer 11a, a light-emitting layer 11b, and a p-type layer 11c sequentially on a surface having Ga polarity of a GaN substrate 10 having a +c-plane main surface through MOCVD (refer to FIG. 2A).

The raw material gases employed for MOCVD are as follows: ammonia (NH₃) as a nitrogen source, trimethylgallium (Ga(CH₃)₃) as a Ga source, trimethylindium (In(CH₃)₃) as an indium source, trimethylaluminum (Al(CH₃)₃) as an aluminum source, silane (SiH₄) as an n-type dopant gas, and bis(cyclopentadienyl)magnesium (Mg(C₅H₅)₂) as a p-type dopant gas, and H₂ or N₂ as a carrier gas.

Subsequently, a part of the semiconductor layer 11 is dry etched from the surface of the p-type layer 11c (the surface opposite to the light-emitting layer 11b side) to form a trench having a depth reaching the n-type layer 11a. A p-electrode 13 is formed so as to cover almost the entire surface of the p-type layer 11c, and an n-electrode 14 is formed on the n-type layer 11a exposed at the bottom of the trench (refer to FIG. 2B). An isolation trench is also formed at the same time.

Next, the GaN substrate 10 is thinned by grinding the rear surface 10a of the GaN substrate 10 (refer to FIG. 2C). Thus, the thickness of the GaN substrate 10 is 50 μm to 200 μm. Mechanical grinding, CMP grinding, or a combination thereof is employed. Thinning the GaN substrate 10 facilitates a step of separating a wafer for each device later.

Subsequently, an isolation trench 20 is formed by laser scanning on an area to separate the wafer for each device, of the rear surface 10a of the GaN substrate 10 (refer to FIG. 2D). The depth of the isolation trench 20 is half the thickness of the GaN substrate 10. Forming the isolation trench 20 facilitates a step of separating the wafer for each device later. Moreover, the cross section of the isolation trench 20 is formed in a V shape, and the side surfaces of the isolation trench 20 are inclined to the main surface of the GaN substrate 10 at an angle of 140° to 160°. The side surfaces of the isolation trench 20 correspond to the arears 10b1 of the side surfaces 10b of the GaN substrate 10 (refer to FIG. 1).

The depth of the isolation trench 20 is not necessarily half the thickness of the GaN substrate 10, and is preferably 0.2 to 0.7 times, more preferably 0.3 to 0.6 times the thickness of the GaN substrate 10.

The isolation trench 20 may be formed by dry etching, dicer cutting other than laser scanning. However, laser scanning is preferable as in Embodiment 1 because no chips or cracks occur in the GaN substrate 10, and a deep isolation trench 20 can be formed. A nano-second laser may be used, for example, with a wavelength of 255 nm, a pulse width of 20 ns to 40 ns, a pulse frequency of 10 Hz to 20 Hz, and an energy per pulse of 0.06 to 0.12 V.

Next, the rear surface 10a of the GaN substrate 10 is wet etched by TMAH(Tetramethylammonium Hydroxide). TMAH is a solution having a concentration of 25% and a temperature of 60° C., and etching was performed for 60 minutes. Wet etching of GaN by TMAH has face orientation dependency. Therefore, the rear surface 10a of the GaN substrate 10 having N-polarity is wet etched so that fine ridges and recesses remain, to form the uneven structure 16 (refer to FIG. 2E). The ridges and recesses become fine by wet etching, thereby improving the light extraction performance, and facilitating the formation of the uneven structure 16.

A strong alkaline aqueous solution such as KOH and NaOH, or phosphoric acid may be used other than TMAH as a wet etching solution to form the uneven structure 16. The uneven structure 16 may be formed by dry etching, and by both wet etching and dry etching. For example, a two-stage uneven structure may be formed, in which fine ridges and recesses are formed by wet etching and large-scale ridges and recesses are formed by dry etching.

Next, through ALD (Atomic Layer Deposition), an antireflection film 15 made of Al₂O₃ is formed along the ridges and recesses of the uneven structure 16 on the rear surface of the GaN substrate so as not to be filled in the recesses, and along the side surfaces of the isolation trench 20 (refer to FIG. 2F). In ALD, TMA and H₂O were used as a precursors gas, the temperature was 50° C. to 300° C., and the pressure was 1×10³ Pa or less. The antireflection film 15 was formed so as to have a thickness of 80 nm to 100 nm.

Since Al₂O₃ atomic layers can be formed one by one using ALD, the antireflection film 15 can have a uniform thickness. Moreover, the thickness of the antireflection film 15 can be precisely controlled in units of atomic layer thickness. Therefore, the antireflection film 15 can be homogenously formed along the ridges and recesses of the uneven structure 16. Moreover, by using ALD, the antireflection film 15 can be formed so as to cover the side surfaces of the isolation trench 20 as well as the rear surface 10a of the GaN substrate 10. The thickness of the antireflection film 15 on the side surfaces of the isolation trench 20 is equal to that on the rear surface 10a of the GaN substrate 10, and a uniform thickness is achieved.

Subsequently, a scribe line is formed by moving a dicer or scriber along the trench for separating the wafer for each device (at a position facing the isolation trench 20) on the +c-plane main surface of the GaN substrate 10 to separate the wafer for each device at the isolation trench 20 and the scribe line position by applying stress. At this time, the areas that have already exposed as the side surfaces of the isolation trench 20 become the areas 10b1 of the side surfaces 10b of the GaN substrate 10, which are inclined in a direction perpendicular to the main surface of the GaN substrate 10. The areas that are newly exposed by separating the wafer for each device become the areas 10b2 of the side surfaces 10b of the GaN substrate 10, which are perpendicular to the main surface of the GaN substrate 10. Through the steps described above, the light-emitting device shown in FIG. 1 is produced. Since the isolation trench 20 is formed on the areas for separating the wafer for each device on the rear surface 10a of the GaN substrate 10, the wafer can be easily separated for each device.

From the above, in the light-emitting device according to Embodiment 1, the antireflection film 15 is formed along the ridges and recesses of the uneven structure 16 on the rear surface 10a of the GaN substrate 10 and along the areas 10b 1 of the side surfaces 10b of the GaN substrate 10, and deviation in thickness of the antireflection film 15 is very small. Thus, the light reflection is effectively prevented at the interface between the rear surface 10a of the GaN substrate 10 and the sealing material, thereby improving the light extraction performance.

### Experiment Results

The results of the experiments on the light-emitting device according to Embodiment 1 will be next described.

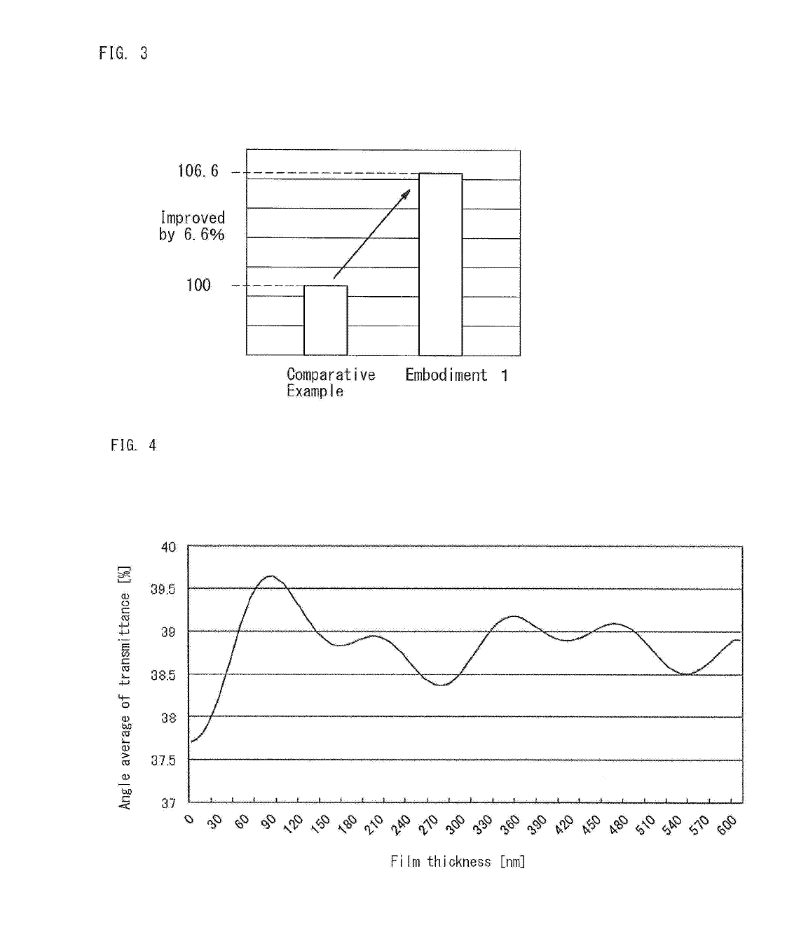

FIG. 3 is a graph showing the comparison of the light outputs between the light-emitting device according to Embodiment 1 and the light-emitting device according to Comparative Example 1. The light-emitting device according to Comparative Example has the same as that of the light-emitting device according to Embodiment 1 except for that the antireflection film 15 was omitted from the light-emitting device according to Embodiment 1.

As shown in FIG. 3, the light output of the light-emitting device according to Embodiment 1 was improved by 6.6% than that of the light-emitting device according to Comparative Example. It was found from this result that reflection was effectively prevented by the antireflection film 15, and thereby the light extraction performance was improved.

FIG. 4 is a graph showing the relationship between the angle average of transmittance and the thickness of Al₂O₃ layer in a model. The angle average of transmittance is defined as the average of transmittance with respect to various incident angles of a light. The model has a structure in which the Al₂O₃ layer having a refractive index of 1.65 and the sealing material having a refractive index of 1.5 are sequentially deposited on the GaN layer having a refractive index of 2.4. When light is incident from the rear surface of the GaN layer (the surface opposite to the Al₂O₃ layer side) of the model, the angle averages of transmittance were obtained by simulation by varying the thicknesses of the Al₂O₃ layer. The angle average was taken for the incident angles from 0° to 90°.

As shown in FIG. 4, there was a peak where the angle average of transmittance is highest when the Al₂O₃ layer has a thickness of 100 nm. It was found from the simulation results that in the light-emitting device according to Embodiment 1, the thickness of the antireflection film 15 is, preferably, in the vicinity of 90 nm, 80 nm to 100 nm, and more preferably, 85 nm to 95 nm.

### Variations

In the present invention, the substrate is not limited to a GaN substrate, and a substrate made of any material may be employed as long as the substrate is formed of Group III nitride semiconductor. The conductive type of the substrate may be either n-type, p-type, or intrinsic. When the n-type Group III nitride semiconductor substrate is employed, Si or Ge may be used as an n-type impurity and Mg may be used as a p-type impurity.

In Embodiment 1, the antireflection film 15 was a single layer. However, it may comprise a plurality of layers. In that case, various structures conventionally used as a multi-layer antireflection film may be employed as the antireflection film of the present invention. However, the antireflection film 15 is preferably a single layer as in Embodiment 1, in view of the balance between the easiness of production and the improvement of transmittance. Since the characteristics can be changed depending on the layer structure in the case where the antireflection film comprises a plurality of layers, transmittance may be increased and material selection may be expanded than in the case where the antireflection film comprises a single layer.

The light-emitting device of the present invention can be employed as a light source of an illumination apparatus or a display apparatus.

What is claimed is:

1. A flip-chip type light-emitting device in which a Group III nitride semiconductor layer is disposed on one surface of a Group III nitride semiconductor substrate, and other surface of the substrate is covered with a sealing material, the light-emitting device comprising:
an uneven structure with ridges and recesses formed on a surface opposite to the semiconductor layer side of the substrate; and
an antireflection film formed continuously on the uneven structure and side surfaces of the substrate along the ridges and recesses of the uneven structure without being filled in recesses, which is made of a material having a refractive index smaller than that of the substrate and larger than that of the sealing material to prevent reflection between the substrate and the sealing material by the interference of light; and
wherein areas of the side surfaces of the substrate at the uneven structure side are inclined with respect to a vertical direction of the main surface of the substrate, and other areas of the side surfaces of the substrate are vertical to the main surface of the substrate; and
wherein the antireflection film is formed on the inclined side surface areas of the substrate and not formed on the vertical side surface areas of the substrate.

2. The light-emitting device according to claim 1, wherein the substrate comprises GaN, and the antireflection film is a single layer made of Al₂O₃.

3. The light-emitting device according to claim 2, wherein the thickness of the antireflection film is 80 nm to 100 nm.

4. The light-emitting device according to claim 1, wherein the standard deviation of the thickness of the antireflection film is 10 nm or less.

5. The light-emitting device according to claim 2, wherein the standard deviation of the thickness of the antireflection film is 10 nm or less.

6. The light-emitting device according to claim 3, wherein the standard deviation of the thickness of the antireflection film is 10 nm or less.

7. A method for producing a flip-chip type light-emitting device in which a Group III nitride semiconductor layer is disposed on one surface of a Group III nitride semiconductor substrate, and other light output surface of the substrate is covered with a sealing material, the method for producing the light-emitting device comprising:
forming an isolation trench on the light output surface of the substrate to separate a wafer for each device;
forming an uneven structure with ridges and recesses on the light output surface of the substrate; and
forming an antireflection film continuously along the ridges and recesses of the uneven structure and the side surfaces of the substrate through ALD, which is made of a material having a refractive index smaller than that of the substrate and larger than that of the sealing material to prevent reflection between the substrate and the sealing material by the interference of light.

8. The method for producing the light-emitting device the according to claim 7, wherein the isolation trench is formed by laser.

9. The method for producing the light-emitting device the according to claim 7, wherein the uneven structure is formed by wet etching.

10. The method for producing the light-emitting device the according to claim 8, wherein the uneven structure is formed by wet etching.

11. The method for producing the light-emitting device the according to claim 7, wherein the antireflection film is a single Al₂O₃ layer.

12. The method for producing the light-emitting device the according to claim 8, wherein the antireflection film is a single Al₂O₃ layer.

13. The method for producing the light-emitting device the according to claim 9, wherein the antireflection film is a single Al₂O₃ layer.

14. The method for producing the light-emitting device the according to claim 7, wherein the antireflection film is formed so as to have a thickness of 80 nm to 100 nm.

15. The method for producing the light-emitting device the according to claim 8, wherein the antireflection film is formed so as to have a thickness of 80 nm to 100 nm.

16. The method for producing the light-emitting device the according to claim 9, wherein the antireflection film is formed so as to have a thickness of 80 nm to 100 nm.

17. The method for producing the light-emitting device the according to claim 10, wherein the antireflection film is formed so as to have a thickness of 80 nm to 100 nm.

18. The method for producing the light-emitting device the according to claim 11, wherein the antireflection film is formed so as to have a thickness of 80 nm to 100 nm.

19. The method for producing the light-emitting device the according to claim 12, wherein the antireflection film is formed so as to have a thickness of 80 nm to 100 nm.

20. The method for producing the light-emitting device the according to claim 13, wherein the antireflection film is formed so as to have a thickness of 80 nm to 100 nm.
